(19) United States
(12) Patent Application Publication
(10) Pub. No.: US 2007/0246769 A1
(43) Pub. Date: Oct. 25, 2007

(54) SEMICONDUCTOR DEVICE INCLUDING ADJACENT TWO INTERCONNECTION LINES HAVING DIFFERENT DISTANCES THEREBETWEEN

(75) Inventor: Nobuyuki Nakamura, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/739,569

(22) Filed: Apr. 24, 2007

(30) Foreign Application Priority Data
Apr. 25, 2006 (JP) 2006-120079

(51) Int. Cl. H01L 29/788

(52) U.S. Cl. 257/315

(57) ABSTRACT

A semiconductor device includes an interconnection layer including adjacent two interconnection lines extending adjacent to each other. A plurality of contact plugs pass through the space between the adjacent two interconnection lines. The adjacent two interconnection lines have different distances therebetween due to a concave-and-convex surface of the sidewall of the adjacent two interconnection lines.

This application is based upon and claims the benefit of priority from Japanese patent application No. 2006-120079 filed on Apr. 25, 2006, the disclosure of which is incorporated herein in its entirety by reference.

### BACKGROUND OF THE INVENTION

1. Field of the Invention

The present invention relates to a semiconductor device and, more particularly, to an improved structure of a semiconductor device including two interconnection lines extending parallel to one another in a single interconnection layer. The present invention also relates to a method for manufacturing such an interconnection structure in a semiconductor device.

2. Description of the Related Art

In a semiconductor device such as a DRAM (Dynamic Random Access Memory), memory cells each for storing data are arranged on a semiconductor substrate in an array, and interconnection lines for driving the memory cells are configured to extend in the row and column directions on the semiconductor substrate. Further, conductive plugs are formed to pass through the space between adjacent two of the interconnection lines in the direction perpendicular to the substrate surface. The conductive plugs may connect together a MIS (Metal Insulator Semiconductor) transistor formed on the semiconductor substrate and a capacitor or interconnection line overlying the semiconductor substrate.

Along with the recent remarkable reduction in the design rule of the semiconductor devices, the space between adjacent two of the interconnection lines has drastically become smaller. If the ratio (i.e., aspect ratio) of the thickness of the interconnection lines to the space between the interconnection lines is excessively large due to the reduction in the space therebetween, an interlayer dielectric film covering the interconnection lines may involve a defective filling structure in the space between the interconnection lines, thereby causing a short-circuit failure between adjacent plugs. FIG. 7 is a top plan view showing such a situation where a short-circuit failure occurs between adjacent contact plugs 19 (19₁ and 19₂) penetrating the space between adjacent interconnection lines 14 (14₁ and 14₂).

In FIG. 7, upon deposition of an interlayer dielectric film to cover the interconnection lines 14, a defective deposition may occur in the space between the interconnection lines 14₁ and 14₂ to generate a void 17 extending parallel to and between the adjacent interconnection lines 14₁ and 14₂ in the interlevel dielectric film. After the deposition of the interlayer dielectric film, contact holes 18 penetrating the interlayer dielectric film are formed between the interconnection lines 14₁ and 14₂ by etching, and thereafter a conductive material is deposited and polished to form contact plugs 19 in the contact holes 18. If the contact holes 18 are located in contact with the void 17, the conductive material 22 embedded in the void 17 upon deposition of the contact plugs 19 causes a short-circuit failure between adjacent contact plugs 19₁ and 19₂.

In order to prevent the short-circuit failure from occurring between the contact plugs due to the presence of a void, Patent Publication JP-2001-338977A describes a structure wherein a sidewall protection film is formed on the sidewall of the contact holes in the process step between the step of forming the contact holes and the step of deposition for the contact plugs.

In the technique described in JP-2001-338977A, the sidewall protection film formed on the sidewall of the contact holes cuts the path between the void and the contact holes, thereby preventing the short-circuit failure from occurring between adjacent contact plugs through the void. The technique of this patent publication, however, lo requires the additional steps for deposing a dielectric film in the contact holes and removing a portion of the deposited dielectric film on the bottom of the contact holes, to thereby leave the sidewall protection film. The additional steps reduce the through-put of the process for manufacturing the semiconductor devices.

### SUMMARY OF THE INVENTION

In view of the above, it is an object of the present invention to provide a semiconductor device having a structure wherein contact plugs penetrate a dielectric film between adjacent interconnection lines, which is capable of preventing a short-circuit failure due to a void from occurring between adjacent contact plugs.

It is another object of the present invention to provide a method for manufacturing the semiconductor device as described above.

The present invention provide, in a first aspect thereof, a semiconductor device including: a plurality of interconnection lines formed in a common layer; and including adjacent two interconnection lines extending adjacent to each other, wherein a space between the adjacent two interconnection lines has a plurality of space regions arranged along an extending direction of the adjacent two interconnection lines, the adjacent two interconnection lines having different distances therebetween corresponding to the space regions.

The present invention provides, in a second aspect thereof, a method for manufacturing a semiconductor device including: depositing an interconnection layer on a semiconductor substrate; patterning the interconnections layer to form at least two interconnection lines extending adjacent to each other in an interconnection layer, wherein a space between the adjacent two interconnection lines has a plurality of space regions arranged along an extending direction of the adjacent two interconnection lines, the adjacent two interconnection lines having different distances therebetween corresponding to the space regions.

The above and other objects, features and advantages of the present invention will be more apparent from the following description, referring to the accompanying drawings.

### BRIEF DESCRIPTION OF THE DRAWINGS

FIG. 1 is a sectional view showing the configuration of a semiconductor device according to an embodiment of the present invention;

FIG. 2 is a top plan view showing the layout of the semiconductor device shown in FIG. 1, which is taken along line I-I in FIG. 2;

FIGS. 3A to 3D are sectional views of the semiconductor device of FIG. 1, consecutively showing steps of a fabrication process thereof.

FIG. 4 is a top plan view of a mask pattern used in the step of FIG. 3A;

FIG. 5 is a sectional view of the configuration of a semiconductor device according to a first modification of the embodiment;

FIG. 6 is a top plan view of a semiconductor device according to a second modification of the embodiment;

FIG. 7 is a top plan view of a conventional semiconductor device; and

FIG. 8 is a top plan view of a mask pattern used for forming the semiconductor device of FIG. 7.

### DETAILED DESCRIPTION OF THE PREFERRED EMBODIMENTS

Now, exemplary embodiments of the resent invention will be described with reference to accompanying drawings, wherein similar constituent elements are designated by similar reference numerals throughout the drawings.

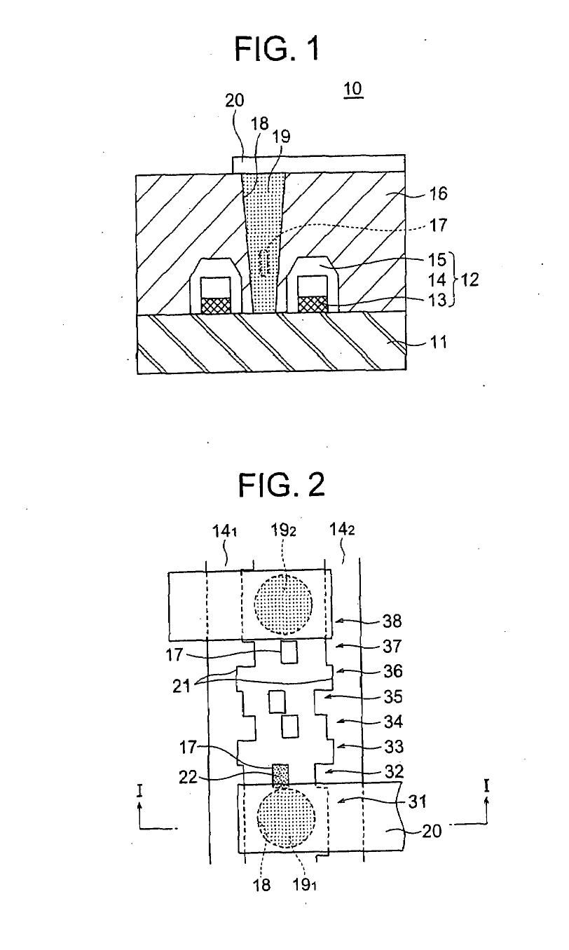

FIG. 1 is a sectional view showing the configuration of a semiconductor device according to an embodiment of the present invention. The semiconductor device, generally designated by numeral 10, includes a semiconductor substrate 11, on which a plurality of combination interconnection structures 12 extend parallel to one another, and an interlayer dielectric film 16 covering the interconnection structures 12. Each of the combination interconnection structures 12 includes a stripe dielectric film 13 formed on the semiconductor substrate 11, an interconnection line 14 formed on the stripe dielectric film 13, and a protection film covering the top and sidewall of the interconnection line 14 together with the sidewall of the stripe dielectric film 13. It is to be noted that FIG. 1 shows only two adjacent interconnection structures out of a plurality of interconnection structures formed on the semiconductor substrate. The depicted interconnection structures may be gate electrodes, for example.

The interconnection line 14 is formed as a single layer or multiple layers of a conductive material, such as tungsten, tungsten silicide, impurities-doped polysilicon, or aluminum, and has a thickness of, e.g., about 150 nm. The protection film 15 is configured by a silicon oxide film formed by, e.g., a plasma-enhanced chemical vapor deposition (CVD) technique, a thermally oxidized film formed by thermal oxidation of the silicon film, or a silica glass. The protection film has a thickness of, e.g., about 20 nm.

The interlayer dielectric film 16 covering the interconnection structures 14 has therein contact holes 18 filled with a contact plug 19. The contact plug 19 penetrates the interlayer dielectric film 16 within the space between adjacent interconnection structures 12. Upon deposition of the interlevel dielectric film 16, a void 17 may be formed in the space between the adjacent interconnection structures 12 due to the insufficient filling capability of the interlevel dielectric film 16, if the aspect ratio of the interconnection structures 12 is large. The void 17 may be formed if the aspect ratio is, for example, 2.5 or larger. The interlevel dielectric film 16 is configured by a silicon oxide film formed by, e.g., a plasma-enhanced chemical vapor deposition (CVD) technique, or a silica glass film formed by spin coating. The protection film has a thickness of, e.g., about 50 to 400 nm.

Overlying interconnection lines 20 each are formed on top of the contact plug 19. The overlying interconnection lines 20 include tungsten, tungsten silicide, impurities-doped polysilicon and/or aluminum. As shown in FIG. 1, if a void 17 is formed within the interlevel dielectric film 16 between adjacent contact plugs 19, the material of the contact plug 19 may enter the void 17.

FIG. 2 is a top plan view showing the layout of the constituent elements in the semiconductor device shown in FIG. 1. FIG. 1 is taken along line I-I in FIG. 2. The contact plugs 19 (19₁ and 19₂) are disposed between the adjacent interconnection lines 14 (14₁ and 14₂), and apart from one another by a predetermined space therebetween along the extending direction of the interconnection lines 14. The sidewall of the interconnection lines 14 near the contact plugs 19 have a convex-and-concave surface, to provide a plurality of different distances for the space (space regions) between the interconnection lines 14₁ and 14₂. Numerals 31 to 38 denote these space regions arranged along the extending direction of the interconnection lines 14.

In the example of FIG. 2, with regard to the space regions 31 to 38, the distance of space regions 32, 34, 35, and 37 are 50 nm, the distance of space regions 31 are 120 nm, and the distance of space regions 33 and 36 are 200 nm. Space regions 31 and 38 receive therein contact plugs 19₁ and 19₂, respectively, whereas the other space regions 32 to 37 do not receive therein the contact plug 19.

In the space regions 32, 34, 35, and 37, in which the distance between the interconnection lines 14₁ and 14₂ is small, the void 17 may be formed as illustrated. Since the space region 32 is located close to the contact plug 19₁, the conductive material 22 configuring the contact plugs 19 is introduced inside the void 17 formed in the space region 32. In the space regions 33 and 36, in which the distance between the interconnection lines 14 is sufficiently large, the void 17 is not formed.

Between the space regions 34 and 35, the sidewalls 21 of the interconnection lines 14₁ and 14₂ near the contact plugs 19₁ and 19₂ are offset in the same direction while allowing an equal distance in the space regions 34 and 35. The offset causes the void 17 in the space region 35 to deviate from the void 17 in the space region 34 by an amount corresponding to the amount of the offset of the sidewalls 21. The deviation of the void 17 from the adjacent void 17 in the direction perpendicular to the extending direction of the interconnect lines 14₁ and 14₂ prevents an electrical connection therebetween with a lower contact resistance.

In the semiconductor device 10 of the present embodiment, the void 17 is not formed in the space regions 33 and 36 in which the distance between the interconnection lines 14 is larger. In addition, the voids 17 are deviated from each other between the adjacent space regions 34 and 35. Thus, the contact plug 19₁ is electrically separated from the contact plug 19₂, whereby occurring of a short-circuit failure between the contact plugs 19₁ and 19₂ via the void 17 is prevented.

It is to be noted that the distance between the interconnection lines 14₁ and 14₂ shown in FIG. 2 is only an example. The distance between the interconnect lines 14₁ and 14₂ in the space regions 31 and 38 receiving therein contact plugs 19₁ and 19₂ may be 200 nm, for example. In addition, although the concave-and-convex surface of the sidewall 21 of the interconnection lines 14 in FIG. 2 is formed in all the spaces regions between the adjacent two contact plugs 19₁ and 192₂, it is sufficient that the sidewall of the interconnection lines 14 have the concave-and-convex surface in at least some of the space regions 32 to 37.

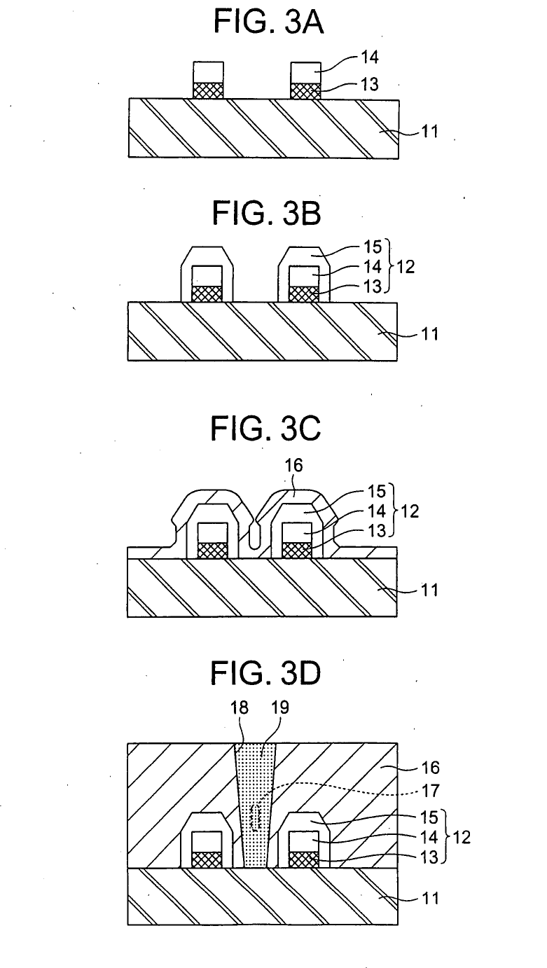

FIGS. 3A to 3D show consecutive steps of a fabrication process for manufacturing the semiconductor device of FIG. 1. A thermal oxidation process is used to form a thermally oxidized film on the semiconductor substrate 11 of FIG. 1, and thereafter a CVD process or sputtering process is used to deposit a conductive film on the thermally oxidized film. Subsequently, a known photolithographic process and a dry etching process are used to pattern the conductive film and thermally oxidized film to form the stripe dielectric films 13 and interconnection lines 14 on the semiconductor substrate 11 (FIG. 3A). In the deposition of the conductive film, a single conductive material or a plurality of conductive materials may be used in a single layer or a plurality of layers.

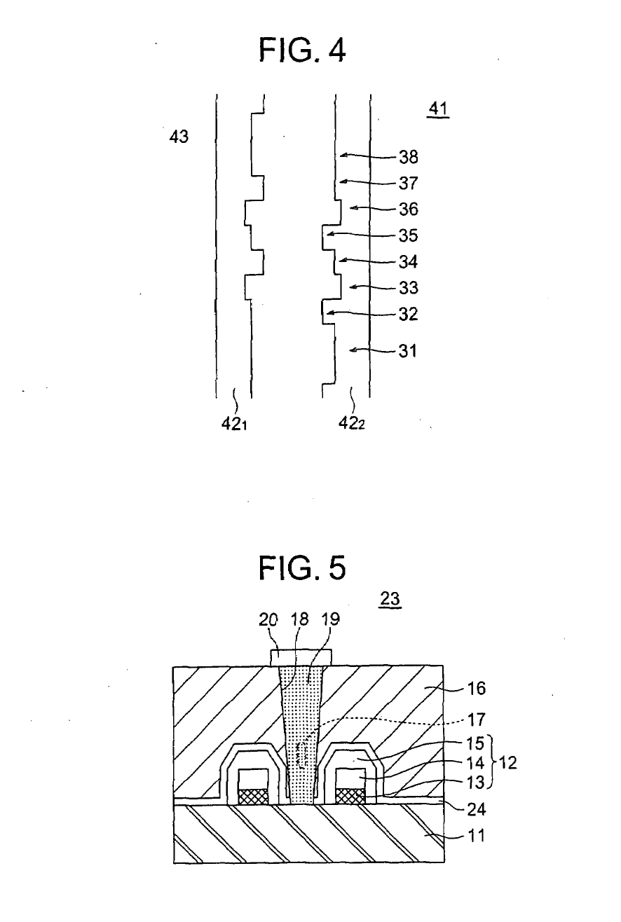

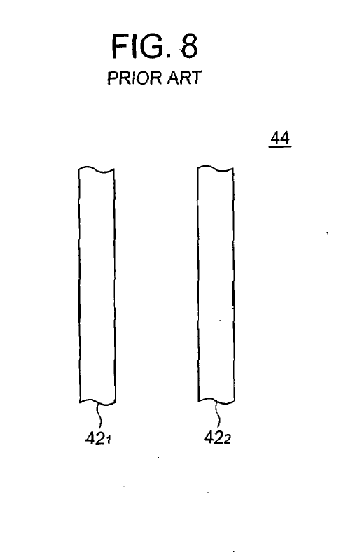

In the patterning process for forming the stripe dielectric films 13 and interconnection lines 14, a mask pattern 41 shown FIG. 4 is used instead of the mask pattern 44 shown in FIG. 8. It is to be noted here that the mask pattern 44 of FIG. 8 is used for manufacturing the conventional semiconductor 100 shown in FIG. 8. The mask pattern 41 shown in FIG. 4 has a pattern corresponding to the planar shape of the interconnection lines 14. The mask pattern 41 shown in FIG. 4 includes stripes 42₁ and 42₂ corresponding to the interconnect lines 14₁ and 14₂, respectively, the stripes 42₁ and 42₂ having a concave-and-convex edge corresponding to the concave-and-convex sidewall of the interconnection lines 14₁ and 14₂.

Subsequently, a known process is used to form the protection film 15 which covers the surface of the exposed stripe dielectric films 13 and interconnection lines (FIG. 3B), thereby obtaining the interconnection structures 12 each including the stripe dielectric film 13, interconnection line 14, and protection film 15. Subsequently, a CVD) process is used to deposit on the semiconductor substrate 11 the interlayer dielectric film 16 which covers the interconnection structures 12. FIG. 3C shows the initial stage of the deposition of the interlevel dielectric film 16. In this stage of deposition, if the aspect ratio is large, the void is formed extending along the extending direction of the interconnection lines 14₁ and 14₂ in the conventional technique. However, in the present embodiment, the sidewall 21 of the interconnection lines 14₁ and 14₂ having a concave-and-convex surface divides the void 17 along the extending direction of the interconnection lines 14.

After completion of the deposition of the interlayer dielectric film 16, a known CMP technique or dry etch-back technique is used to polish or etch the top of the interlayer dielectric film 16, thereby forming a flat-top interlayer dielectric film. Subsequently, a known photolithographic process and a dry etching process are used to form the contact holes 18 which penetrate the interlayer dielectric film 16 in the space between the adjacent interconnection structures 12. The contact holes 18 are formed so as not to be in contact with the interconnection structures 12. Then, the internal of the contact holes 18 is subjected to a wet cleaning process to remove the etching residues remaining within the contact holes 18 after the dry etching.

Subsequently, a conductive material for forming the contact plugs 19 is deposited within the contact holes 18 and on top of the interlayer dielectric film 16. If the contact holes 18 are formed at the location where the void 17 has been formed, the conductive material may be introduced inside the void 17. However, in the present embodiment, since the void 17 is divided in the extending direction of the interconnection lines 14, the conductive material is separated between the adjacent contact plugs 19. Subsequently, a CMP process is used to remove the conductive material deposited on top of the interlayer dielectric film 16, thereby forming the contact plugs 19 made of the conductive material filing the contact holes 18 (FIG. 3D).

Subsequently, a CVD process or sputtering process is used to deposit, on the interlayer dielectric film 16 and contact plugs 19, a conductive material for forming an overlying interconnection layer. Further, a known photolithographic process and a dry etching process are used to pattern the deposited conductive material, thereby forming the overlying interconnection lines 20 shown in FIG. 1, which are in contact with top of the contact plugs 19.

According to the method for manufacturing a semiconductor device of the present embodiment, the patterning process for forming the interconnection lines 14 uses the mask pattern 41 having a concave-and-convex edge for forming the concave-and-convex sidewall of the interconnection lines 14₁ and 14₂. The concave-and-convex sidewall of the interconnection lines provides a plurality of space regions having different distances, thereby preventing the adjacent contact plugs from being short circuited via the void.

The process of the present embodiment uses the mask pattern such as shown in FIG. 4, and does not increase the number of process steps for preventing a short-circuit failure.

FIG. 5 shows the configuration of a semiconductor device according to a first modification of the above embodiment. In the semiconductor deice of this modification generally designated by numeral 23, a thermally oxidized film 24 is formed on the exposed surface of the semiconductor substrate 11 and protection film 15 protecting the interconnection lines 14, and thereafter the interlayer dielectric film 16 is deposited to cover the thermally oxidized film 24. The contact holes 18 and contact plugs 19 are formed to penetrate the interlayer dielectric film 16 and thermally oxidized film 24. In this process for manufacturing the semiconductor device 23, the protection film 15 is first formed, followed by a thermal oxidation process to form the thermally oxidized film 24 on the exposed surface of the semiconductor substrate 11 and protection film 15, and deposition of the interlayer dielectric film 16.

The thermally oxidized film 24 formed on the surface of the protection film 15 generally has a uniform thickness. Thus, by forming the thermally oxidized film 24 before the deposition of the interlayer dielectric film 16, it is possible to reduce the size of the void 17 as compared to the case where the thermally oxidized film 24 is not formed. Further, the thermally oxidized film 24 has a lower etch rate in a wet cleaning process performed for the internal of the contact hole 18. Therefore, even if a void 17 is formed near the thermally oxidized film 24, it is possible to prevent the size of the void 17 from being increased in the wet cleaning process. With the above configuration, it is possible to effectively separate the void 17 and effectively prevent a short-circuit failure between the contact plugs 19. It is to be noted that even if a normal-pressure CVD process is used to form a silicon nitride film instead of the thermally oxidized film 24, a similar advantage can be obtained.

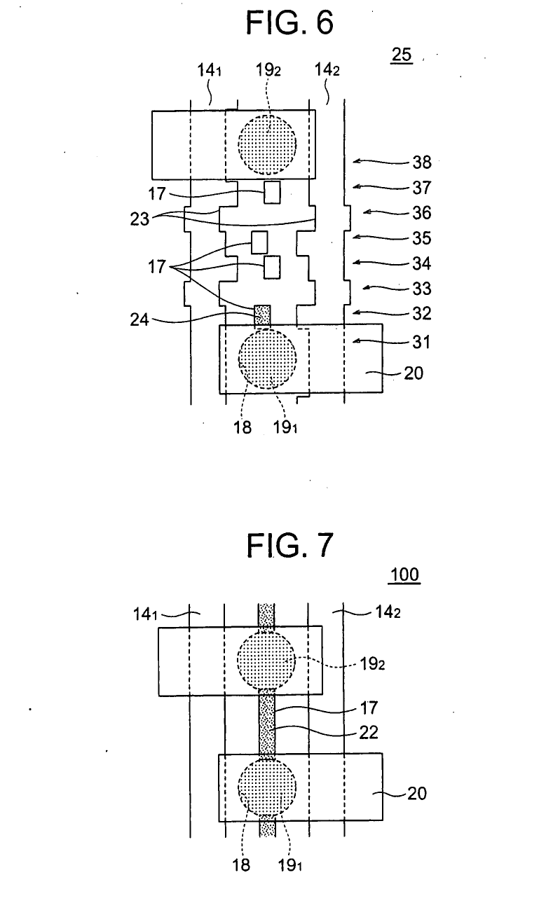

FIG. 6 is a top plan view showing the layout of constituent elements of a semiconductor device according to a second modification of the embodiment. In the semiconductor device of the second modification generally designated by numeral 25, the outer sidewall 21 of the interconnection lines 14₁ and 14₂, which opposes the sidewall defining the space regions, additionally projects outward to have a structure wherein the outer sidewall of the interconnection lines 14₁ and 14₂ has a concave-and-convex surface. In the structure shown in FIG. 2, the interconnect lines 14₁ and 14₂ have a reduced-width portion near the space regions. In this modification, the reduced-width portion is removed by provision of the protruding portion of the outer sidewall near the space regions 33 and 36. Further, in the semiconductor device 25 according to the second modification, an increased-width portion is provided for the interconnection lines 14₁ and 14₂ near the other space regions. This configuration suppresses an increase in the electric resistance of the interconnection lines near the space regions 33 and 36 and rather reduces the overall electric resistance. In manufacturing the semiconductor device 25, a mask pattern corresponding to the planar shape of the interconnection lines 14₁ and 14₂ shown in FIG. 7 is used.

As described above, in the semiconductor device of the embodiment and the modifications, the configuration wherein the adjacent two interconnection lines have therebetween different spaces allows the void formed in the space to be divided in the extending direction of the interconnection lines, thereby preventing a short-circuit failure between contact plugs penetrating the space between the interconnection lines. In addition, this configuration can be achieved only by using a mask pattern having a specific shape, thereby achieving the above advantage without an increase in the number of process steps, and thus at a lower cost.

Although the semiconductor devices of the above embodiment and modifications have interconnection lines 14₁ and 14₂ which are formed on the semiconductor substrate 11 with an intervention of the stripe dielectric films 13, the present invention is also applicable to various types of semiconductor devices such as including interconnection lines formed in a common interconnection layer and extend substantially parallel to one another.

While the present invention has been particularly shown and described with reference to exemplary embodiments and modifications thereof, the present invention is not limited to these embodiments. It will be understood by those of ordinary skill in the art that various changes in form and details be made therein without departing from the spirit and scope of the present invention as defined in the claims.

What is claimed is:

1. A semiconductor device comprising:
a plurality of interconnection lines formed in a common layer and including adjacent two interconnection lines extending adjacent to each other, wherein a space between said adjacent two interconnection lines has a plurality of space regions arranged along an extending direction of said adjacent two interconnection lines, said adjacent two interconnection lines having different distances therebetween corresponding to said space regions.

2. The semiconductor device according to claim 1, wherein a first sidewall of at least one of said adjacent two interconnection lines defining said space has a first surface portion substantially parallel to said extending direction and a second surface portion substantially perpendicular to said extending direction.

3. The semiconductor device according to claim 2, wherein a second sidewall of at least one of said adjacent interconnection lines opposing said first sidewall has a concave-and-convex surface.

4. The semiconductor device according to claim 1, further comprising an interlevel dielectric film overlying said interconnection lines, and at least two contact plugs penetrating said interlevel dielectric film and passing said space between said adjacent two interconnection lines while being insulated therefrom,

5. The semiconductor device according to claim 4, wherein said adjacent two interconnection lines have different distances between said two contact plugs,

6. The semiconductor device according to claim 5, wherein said adjacent two interconnection lines have parallel offsets in a boundary between adjacent two of said space regions.

7. The semiconductor device according to claim 6, wherein said adjacent two of said space regions have an equal space between said adjacent two interconnection lines.

8. The semiconductor device according to claim 1, wherein said interconnection lines each have a protection oxide film covering a top and sidewall of said interconnection lines.

9. The semiconductor device according to claim 8, further comprising a thermally oxide film formed on said protection oxide film and said semiconductor substrate.

10. A method for manufacturing a semiconductor device comprising:
depositing an interconnection layer on a semiconductor substrate;
patterning said interconnection layer to form at least two interconnection lines extending adjacent to each other in an interconnection layer, wherein a space between said adjacent two interconnection lines has a plurality of space regions arranged along an extending direction of said adjacent two interconnection lines, said adjacent two interconnection lines having different distances therebetween corresponding to said space regions.

11. The method according to claim 10, further comprising forming a protection film protecting each of said interconnection lines.

12. The method according to claim 11, further comprising forming a thermally oxide film on said protection film and said semiconductor substrate.
